(19) United States
(12) Patent Application Publication
(10) Pub. No.: US 2010/0239106 A1
(43) Pub. Date: Sep. 23, 2010

(54) Probabilistic Method of Loudspeaker Detection

(75) Inventors: Steven David TRAUTMANN, Tsukuba (JP); Akihiro YONEMOTO, Tokyo (JP); Hiroshi TAKAOKA, Tsukuba (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/407,264

(22) Filed: Mar. 19, 2009

(51) Int. Cl. H03G 5/00; H04R 29/00

(52) U.S. Cl. 381/98; 381/59

(57) ABSTRACT

A method and apparatus for enhancing cutoff detection of a loudspeaker. The method comprising retrieving a loudspeaker model cutoff and model error, generating a probability distribution of the cutoff frequency based on the retrieved models, and utilizing the generated probability distribution to enhance the detection of the cutoff of the loudspeaker.

### BACKGROUND OF THE INVENTION

1. Field of the Invention

Embodiments of the present invention generally relate to a method and apparatus for loudspeaker cutoff detection.

2. Background of the Invention

For applications such as room equalization, loudspeaker equalization and bass management, it is sometimes necessary to measure the frequency response of the loudspeakers. If the low-frequency cutoff of the loudspeakers can be determined, this information can be used to effectively apply bass management, i.e. remove poorly reproduced frequencies and route them to a better loudspeaker such as a subwoofer. However the measured spectrum of a loudspeaker usually contains irregularities caused by reflections and noise, making cutoff detection difficult.

Therefore, there is a need for an improved loudspeaker cutoff detection method and apparatus.

### SUMMARY OF THE INVENTION

Embodiments of the present invention relate to a method and apparatus for enhancing cutoff detection of a loudspeaker. The method comprising retrieving a loudspeaker model cutoff and model error, generating a probability distribution of the cutoff frequency based on the retrieved models, and utilizing the generated probability distribution to enhance the detection of the cutoff of the loudspeaker.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. In this application, a computer readable processor is any medium accessible by a computer for saving, writing, archiving, executing and/or accessing data. Furthermore, the method described herein may be coupled to a processing unit, wherein said processing unit is capable of performing the method.

FIG. 1 is an embodiment of a bass management filter design;

FIG. 2 is an embodiment of a front left loudspeaker measurement;

FIG. 3 is an embodiment of an effect of M as a shape parameter for critical u=0.6436, maxiflat u=1.5538 and huge u=1000.0 cases;

FIG. 4 is an embodiment of a normalized probability of cutoff frequency ω_{c} with u from 0.5 to 500.0 and ω_{c} from 1.0 Hz to 748.5 Hz (thatched region is unrealizable);

FIG. 5 is an embodiment of an audio based method;

FIG. 6 is a flow diagram depicting an embodiment of a method for enhancing a loudspeaker cutoff detection; and

FIG. 7 is a flow diagram depicting an embodiment of a normalization method to make a probability distribution.

### DETAILED DESCRIPTION

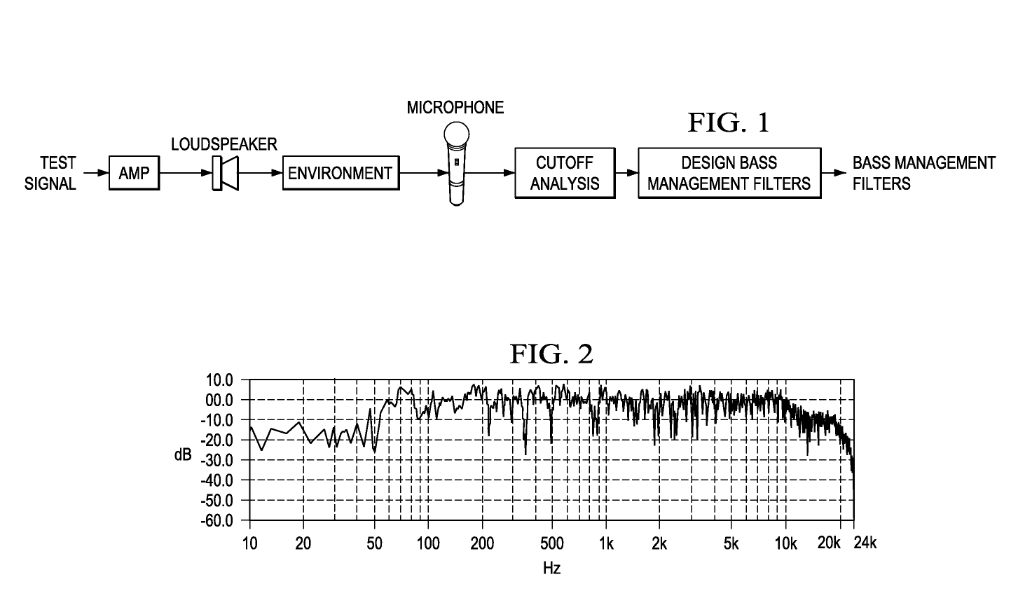

Bass management refers to routing the low frequency part of the signal to the most effective transducer, typically a subwoofer. Thus, the upper cutoff frequency of the subwoofer and lower cutoff frequencies of the other loudspeakers are usually known. If a subwoofer is not available, a technique, such as bass-boost (creates the sensation of more bass) may be applied. Such technique may be utilized when the loudspeaker cutoff is known to be too high. For these and other applications, it is useful to be able to estimate the lower cutoff frequency of regular loudspeakers. FIG. 1 shows how a loudspeaker measurement is taken with a microphone, analyzed for cutoff frequency, which is then used to design or choose appropriate bass management filters.

The measurement may be the same as loudspeaker equalization. Loudspeaker equalization refers to filters applied to a signal which are designed to compensate for the loudspeaker response. Generally, a known test signal is applied to the loudspeaker. The output is picked up by a microphone with a known frequency response. The unknown system, such as, amplifier, loud-speaker, environment, may be tested by applying a known test signal and recording the output. The frequency response may be derived using standard techniques. This measured frequency response, used primarily to design equalization filters, in principle may be used for several addition purposes including distance detection, polarity detection and cutoff detection. However, the spectrum of the measured system is typically not smooth, as shown in FIG. 2. FIG. 2 is an embodiment of a measurement for the front left speaker of a 5 speaker plus woofer system. The irregularity in the spectrum makes accurate cutoff estimation difficult.

The basic approach of this method is to generate a probability distribution of the cutoff frequency based on a model of loudspeaker cutoff and a Gaussian model of error. The error is the difference between the model and measurement. The error is caused by several factors, such as, background noise, measurement error, and room and speaker reflections. Such error may effect choosing the wrong model function.

The background noise and measurement error are likely to be approximately Gaussian. However, assuming the loudspeaker model is accurate, the largest source of error is usually the room and speaker reflections, which are generally non-Gaussian. Using a Gaussian error model may lead to relatively straight forward mathematical formulations.

After the loudspeaker model and error model are set, a probability distribution for the cutoff frequency remains, which may also require utilizing cutoff frequency as one of the parameters, applying Bayes' Theorem and eliminating the other “nuisance” parameters. Finally, this distribution can be analyzed and action taken based on the result.

A closed-box loudspeaker system model is

$$G ( s ) = \frac{{s}^{2} {T}_{C}^{2}}{{s}^{2} {T}_{C}^{2} + {sT}_{C} / {Q}_{TC} + 1} \qquad ( 1 )$$

where Q_{TC} is the total Q of the system at f_{C}, with f_{C} being the resonance frequency of closed-box system, and T_{C} is the time constant 1/2πf_{C}. The frequency response of this model is

$$G ( j ω ) = \frac{- {ω}^{2} {T}_{C}^{2}}{- {ω}^{2} {T}_{C}^{2} + j ω {T}_{C} / {Q}_{TC} + 1} \qquad ( 2 )$$

and the magnitude response is

$${\vert G ( j ω ) \vert}^{2} = G ( jω ) \overline{G ( j ω )} \\ = \frac{{ω}^{4} {T}_{C}^{4}}{{ω}^{′ 1} {T}_{C}^{4} - 2 {ω}^{2} {T}_{C}^{2} + {{ω}^{2} ( {T}_{C} / {Q}_{TC} )}^{2} + 1} . \qquad ( 3 )$$

Now the cutoff frequency ω_{c} is defined as the point at which

$${\vert G ( j ω ) \vert}^{2} = \frac{1}{2} . \qquad ( 4 )$$

Using this constraint and solving for T_{C}/Q_{TC} we have

$$\begin{matrix}{ω}_{c}^{4} {T}_{C}^{4} = \frac{1}{2} ( {ω}_{c}^{4} {T}_{C}^{4} - 2 {ω}_{c}^{2} {T}_{C}^{2} + {{ω}_{c}^{2} ( {T}_{C} / {Q}_{TC} )}^{2} + 1 ) & ( 5 ) \\ 2 {ω}_{c}^{4} {T}_{C}^{4} - {ω}_{c}^{4} {T}_{C}^{4} + 2 {ω}_{c}^{2} {T}_{C}^{2} - 1 = {{ω}_{c}^{2} ( {T}_{C} / {Q}_{TC} )}^{2} & ( 6 ) \\ {T}_{C} / {Q}_{TC} = \sqrt{{ω}_{c}^{2} {T}_{C}^{4} + 2 {T}_{C}^{2} - \frac{1}{{ω}_{c}^{2}}} & ( 7 )\end{matrix}$$

Substituting (7) into (3) gives

$${\vert G ( j ω ) \vert}^{2} = \frac{{ω}^{4} {T}_{C}^{4}}{{ω}^{4} {T}_{C}^{4} - 2 {ω}^{2} {T}_{C}^{2} + {ω}^{2} ( {ω}_{c}^{2} {T}_{C}^{4} + 2 {T}_{C}^{2} - \frac{1}{{ω}_{c}^{2}} ) + 1} \\ = \frac{{T}_{C}^{4} {ω}^{4}}{1 - \frac{{ω}^{2}}{{ω}_{c}^{2}} + {T}_{C}^{4} {ω}_{c}^{2} {ω}^{2} + {T}_{C}^{4} {ω}^{4}} \qquad ( 8 )$$

eliminating the Q_{TC} parameter and introducing the cutoff ω_{c} as a new parameter.

Equation (8) takes two parameters, T_{C} and ω_{c}, and one variable ω which represents a frequency. Since the data is taken at discrete bin frequencies, we will usually index this variable with k as ωₖ to mean the frequency at the k^{th} bin which can be interpreted in Hz depending on sampling rate and FFT size. To remain neutral during calculation frequency is measured in bins, i.e. ωₖ=k. However in this paper the sampling rate is always 48 kHz and the FFT size is always 32,768 giving a conversion factor of ≈1.46475 Hz per bin. It is also convenient to write the cutoff frequency ω_{c} on the same scale so that ω_{c}=ωₖ when c=k. However c need not be restricted to be an integer.

The T_{C} parameter determines the shape of the model frequency response once ω_{c} is fixed. However the effect of T_{C} depends on ω_{c}. For instance a given value of T_{C} may make the frequency response peaky for some an and very flat for other ω_{c}. This is due to the fact that scaling ω_{c} and ω by the same amount α in (8) gives

$$\frac{{α}^{4} {T}_{C}^{4} {ω}^{4}}{1 - \frac{{ω}^{2}}{{ω}_{c}^{2}} + {α}^{4} {T}_{C}^{4} {ω}_{c}^{4} {ω}^{2} + {α}^{4} {T}_{C}^{4} {ω}^{4}} \neq \frac{{T}_{C}^{4} {ω}^{4}}{1 - \frac{{ω}^{2}}{{ω}_{c}^{2}} + {T}_{C}^{4} {ω}_{c}^{2} {ω}^{2} + {T}_{C}^{4} {ω}^{4}} . \qquad ( 9 )$$

However making the substitution u−ω_{c}T_{C} in (8) gives

$${\vert G ( j ω ) \vert}^{2} = \frac{\frac{{u}^{′1}}{{ω}_{c}^{′1}} {ω}^{4}}{1 - \frac{{ω}^{2}}{{ω}_{c}^{2}} + \frac{{u}^{4}}{{ω}_{c}^{2}} {ω}^{2} + \frac{{u}^{4}}{{ω}_{c}^{4}} {ω}^{4}} \\ = \frac{{u}^{4} {ω}^{4}}{{ω}_{c}^{4} - {ω}^{2} {ω}_{c}^{2} + {u}^{4} {ω}^{2} {ω}_{c}^{2} + {u}^{4} {ω}^{4}} \qquad ( 10 )$$

so that after scaling ω and ω_{c} by α it becomes the case that

$$\frac{{α}^{4} {u}^{4} {ω}^{4}}{\begin{matrix}{α}^{4} {ω}_{c}^{4} - {α}^{4} {ω}^{2} {ω}_{c}^{2} + \\ {α}^{4} {u}^{4} {ω}^{2} {ω}_{c}^{2} + {α}^{4} {u}^{4} {ω}^{4}\end{matrix}} = \frac{{u}^{4} {ω}^{4}}{{ω}_{c}^{4} - {ω}^{2} {ω}_{c}^{2} + {u}^{4} {ω}^{2} {ω}_{c}^{2} + {u}^{4} {ω}^{4}} \qquad ( 11 )$$

and the shape is persevered.

Note that u should be constrained to physically realizable values derived from the constraint T_{C}/Q_{TC}≧0 from (7). We also have from (7) that

$$\begin{matrix}{ω}_{c}^{2} {T}_{C}^{4} + 2 {T}_{C}^{2} - \frac{1}{{ω}_{c}^{2}} \geq 0 \\ or & ( 12 ) \\ {ω}_{c}^{4} {T}_{C}^{4} + 2 {ω}_{c}^{2} {T}_{C}^{2} \geq 1 & ( 13 )\end{matrix}$$

so completing the square we have

w_{c}⁴T_{C}⁴+2ω_{c}²T_{C}²+1≧1 (14)

and

(w^{c}²T_{C}²+1)²≧2. (15)

Thus

ω_{c}²T_{C}²+1≧\sqrt{2} (16)

and finally

u=ω_{c}T_{C}≧\sqrt{\sqrt{2}−1}≈0.643594252905582742. (17)

Thus, u cannot be less than the critical value ≈0.6436.

Another important value of u is that which makes the frequency response maximally flat. A flat response is often a goal in loudspeaker design, so the value of u that achieves this will likely be a good value for a loudspeaker model.

The maxiflat value of u can be found by plugging the denominator of (1) into the quadratic formula and making the discriminant 0 as follows:

$$\begin{matrix}0 = \sqrt{{( \frac{{T}_{C}}{{Q}_{TC}} )}^{2} - 4 {T}_{C}^{2}} ⇒ \frac{{T}_{C}^{2}}{{Q}_{TC}^{2}} = 4 {T}_{C}^{2} \\ \text{and since} & ( 18 ) \\ 4 {T}_{C}^{2} = \frac{{T}_{C}^{2}}{{Q}_{TC}^{2}} = {ω}_{c}^{2} {T}_{C}^{4} + 2 {T}_{C}^{2} - \frac{1}{{ω}_{c}^{2}} \\ \text{we have} & ( 19 ) \\ {ω}_{c}^{2} {T}_{C}^{4} - 2 {T}_{C}^{2} - \frac{1}{{ω}_{c}^{2}} = 0 \\ \text{so that} & ( 20 ) \\ {T}_{C}^{2} = \frac{1 + \sqrt{2}}{{ω}_{c}^{2}} . \\ \text{and} & ( 21 ) \\ u = {T}_{C} {ω}_{c} = \sqrt{1 + \sqrt{2}} \approx 1.5537739740300374 . & ( 22 )\end{matrix}$$

Equation (10) may need to be scaled by an amplitude A in order to best fit the data. This is important since generally the amplitude of the data is unknown. Thus we can define our basic model to be

$${Am}_{k} ( {ω}_{c} , u ) = A {\vert G ( {jω}_{k} ) \vert}^{2} = A \frac{{u}^{4} {ω}_{k}^{4}}{{ω}_{c}^{4} - {ω}_{k}^{2} {ω}_{c}^{2} + {u}^{4} {ω}_{k}^{2} {ω}_{c}^{2} + {u}^{4} {ω}_{k}^{4}} . \qquad ( 23 )$$

Substituting (22) into (23) gives

$${Am}_{k} ( {ω}_{c} ) = A \frac{( 3 + 2 \sqrt{2} ) {ω}_{k}^{4}}{{ω}_{c}^{4} + ( 2 + 2 \sqrt{2} ) {ω}_{k}^{2} {ω}_{c}^{2} + ( 3 + 2 \sqrt{2} ) {ω}_{k}^{4}} . \qquad ( 24 )$$

as a maxiflat loudspeaker model depending only on parameters of amplitude A and cutoff frequency ω_{c}.

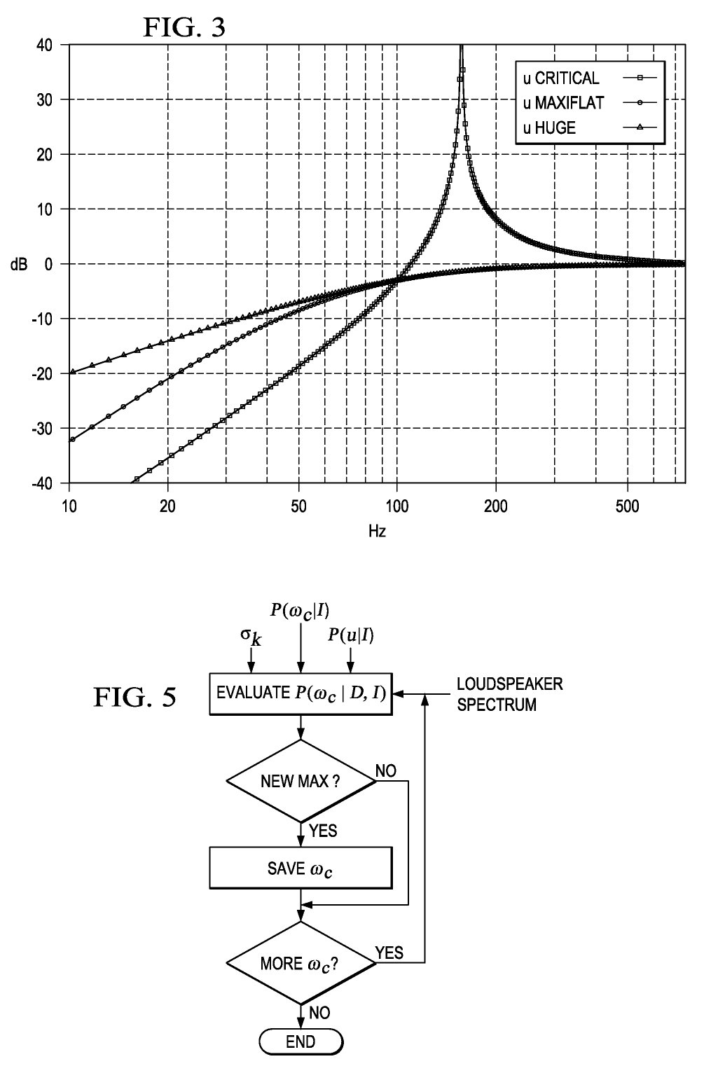

FIG. 3 illustrates the effect of u on the frequency response for the basic model (23) with ω_{c} set at 100 Hz and A=1. Shown are frequency responses with the critical value of (17) where u=0.6436 and maxiflat value of (22) where u=1.5538 and a “huge” value of u=1000.0. In the critical value case, the resonance peak heads toward ∝ while the maxiflat case is close to the huge case, but below the cutoff frequency drops off more rapidly.

By error we mean the difference between the model and the measured value. For this error, a gaussian model is assumed. Letting D represent our data, which is the squared magnitude of a measured loudspeaker spectrum X, letting dₖ represent the data at frequency bin index k, i.e. dₖ=|X[k]|², letting mₖ, A, u and ω_{c} represent the model and parameters used in (23) and letting I represent our models for loudspeakers and error, the likelihood for a particular set of parameters can be expressed as

$$P ( D \vert A , u , {ω}_{c} , I ) = {\prod }_{k} \frac{1}{{σ}_{k} \sqrt{2 π}} exp ( - \frac{1}{2 {σ}_{k}^{2}} {( {d}_{k} - {Am}_{k} ( {ω}_{c} , u ) )}^{2} ) \qquad ( 25 )$$

where σₖ is the standard deviation of the noise at index k. Here the “noise” is really the error at each frequency bin which can be frequency dependent. These σₖ can be treated as a set of additional parameters, but for now we will assume these are known since doing so doesn't affect the rest of the derivations. The σₖ can be thought of as a weighting on the frequency, a smaller σₖ value indicates more certainty about the dₖ value and thus the error at that frequency counts more. As a frequency weighting, these σₖ can also be modified to force the algorithm to weigh some frequencies more than others. Conversely, if there is no reason to emphasize the contribution at any frequency, all σₖ can be set to the same value.

Equation (25) is called the likelihood of the parameters, since the data is fixed and the parameters can vary. It can be interpreted as saying that the probability of the data given the loudspeaker model, gaussian noise model, and a set of model parameters is just the product of the independent probability densities that gaussian noise makes up the difference between the model with those parameters and the data. The parameter values which maximize the probablity of the data are those that minimize the sum of the squared differences with the data, and are known as the least squares solution.

Bayes' Theorem follows directly from the definition of conditional probability as follows:

$$\begin{matrix}P ( AB ) = P ( A \vert B ) P ( B ) \\ = P ( B \vert A ) P ( A ) ⇒ P ( B \vert A ) \\ = \frac{P ( A \vert B ) P ( B )}{P ( Λ )}\end{matrix} \qquad ( 26 )$$

where A and B can be basically any statements for which conditional probability makes sense. Applying (26) to (25) gives

$$P ( A , u , {ω}_{c} \vert D , I ) = \frac{P ( D \vert A , u , {ω}_{c} , I ) P ( A , u , {ω}_{c} \vert I )}{P ( D \vert I )} . \qquad ( 27 )$$

Thus, in addition to the likelihood P(D|A, u, ω_{c}, I) given by (25), we need a prior probability P(A, u, ω_{c}|I) and a normalizing term P(D|I) in order to get our posterior probability P(A, u, ω_{c}|D, I). However another step is then to eliminate the “nuisance” parameters A and u to give the posterior probability of the cutoff frequency P(w_{c}|D, I). The elimination of A as a “nuisance” parameter can be achieved by exact marginalization.

Let {θ} be a set of parameters, A be a scale (amplitude) parameter, dₖ be the k^{th} data value and mₖ be the model value at index k with parameters {θ}. Then using the gaussian error model we have

$$P ( D \vert \{ θ \} , A , I ) = {\prod }_{k} \frac{1}{{σ}_{k} \sqrt{2 π}} exp ( - \frac{1}{2 {σ}_{k}^{2}} {( {d}_{k} - {Am}_{k} )}^{2} ) .$$

Note that parameter A appears as a scale term outside of the model itself, which only takes parameters {θ}. Then we have

$$\begin{matrix}P ( D \vert \{ θ \} , A , I ) = ( {\prod }_{k} \frac{1}{{σ}_{k} \sqrt{2 π}} ) exp ( - {\sum }_{k} \frac{1}{2 {σ}_{k}^{2}} {( {d}_{k} - {Am}_{k} )}^{2} ) \\ = ( {\prod }_{k} \frac{1}{{σ}_{k} \sqrt{2 π}} ) \\ exp ( {\sum }_{k} \frac{1}{2 {σ}_{k}^{2}} ( {d}_{k}^{2} 2 Λ {d}_{k} {m}_{k} \vert {Λ}^{2} {m}_{k}^{2} ) ) \\ = ( {\prod }_{k} \frac{1}{{σ}_{k} \sqrt{2 π}} ) exp ( - {\sum }_{k} \frac{1}{2 {σ}_{k}^{2}} {d}_{k}^{2} ) \\ exp ( - {\sum }_{k} \frac{1}{2 {σ}_{k}^{2}} ( - 2 {Ad}_{k} {m}_{k} + {A}^{2} {m}_{k}^{2} ) ) \\ = ( {\prod }_{k} \frac{1}{{σ}_{k} \sqrt{2 π}} ) exp ( - {\sum }_{k} \frac{1}{2 {σ}_{k}^{2}} {d}_{k}^{2} ) \\ exp ( - {A}^{2} ( {\sum }_{k} \frac{1}{2 {σ}_{k}^{2}} {m}_{k}^{2} ) + A ( {\sum }_{k} \frac{1}{{σ}_{k}^{2}} {d}_{k} {m}_{k} ) ) .\end{matrix}$$

From Bayes' Theorem we have

$$\begin{matrix}P ( \{ θ \} , A \vert D , I ) = \frac{P ( \{ θ \} , A \vert I ) P ( D \vert \{ θ \} , A , I )}{P ( D \vert I )} \\ = \frac{P ( \{ θ \} \vert I ) P ( A \vert I ) P ( D \vert \{ θ \} , A , I )}{\int \int P ( D , \{ θ \} , A \vert I ) d \{ θ \} d A} \\ = \frac{P ( \{ θ \} I ) P ( D \vert \{ θ \} , A , I ) P ( A \vert I )}{\int d \{ θ \} \int d AP ( \{ θ \} \vert I ) P ( D \vert \{ θ \} , A , I ) P ( AI )}\end{matrix}$$

with the integration ranges and prior probabilities appropriately chosen for the parameters. We would like to marginalize A.

$$\begin{matrix}P ( \{ θ \} \vert D , I ) = \int d AP ( \{ θ \} , A \vert D , I ) \\ = \frac{P ( \{ θ \} \vert I ) \int d AP ( D \vert \{ θ \} , A , I ) P ( A \vert I )}{\int d \{ θ \} P ( \{ θ \} \vert I ) \int d AP ( D \vert \{ θ \} , A , I ) P ( A \vert I )}\end{matrix}$$

$$\int d A exp ( - {C}_{0} {A}^{2} + {C}_{1} A ) = \frac{\sqrt{π} crf ( \frac{2 A {C}_{0} - {C}_{1}}{2 \sqrt{{C}_{0}}} )}{2 \sqrt{{C}_{0}} exp ( - \frac{{C}_{1}^{2}}{4 {C}_{0}} )} + constant$$

So, if we choose a flat prior for P(A|I) and a range of (−∞, ∞) we have

$${\int }_{- ∞}^{∞} d A exp ( - {C}_{0} {A}^{2} + {C}_{1} A ) = \frac{\sqrt{π} exp ( \frac{{C}_{1}^{2}}{4 {C}_{0}} )}{\sqrt{{C}_{0}}}$$

$$\text{and with}$$

$${C}_{0} = ( {\sum }_{k} \frac{1}{2 {σ}_{k}^{2}} {m}_{k}^{2} )$$

$${C}_{1} = ( {\sum }_{k} \frac{1}{{σ}_{k}^{2}} {d}_{k} {m}_{k} )$$

$$\text{we have}$$

$$\begin{matrix}{\int }_{- ∞}^{∞} d AP ( D \vert \{ θ \} , A , I ) P ( A \vert I ) = ( {\prod }_{k} \frac{1}{{σ}_{k} \sqrt{2 π}} ) exp ( - {\sum }_{k} \frac{1}{2 {σ}_{k}^{2}} {d}_{k}^{2} ) {\int }_{- ∞}^{∞} d A exp ( - {A}^{2} ( {\sum }_{k} \frac{1}{2 {σ}_{k}^{2}} {m}_{k}^{2} ) + A ( {\sum }_{k} \frac{1}{{σ}_{k}^{2}} {d}_{k} {m}_{k} ) ) P ( A \vert I ) \\ = ( {\prod }_{k} \frac{1}{{σ}_{k} \sqrt{2 π}} ) exp ( - {\sum }_{k} \frac{1}{2 {σ}_{k}^{2}} {d}_{k}^{2} ) \frac{ \sqrt{π}}{\sqrt{{\sum }_{k} \frac{1}{2 {σ}_{k}^{2}} {m}_{k}^{2}}} exp ( \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} )\end{matrix}$$

$$\text{so that}$$

$$\begin{matrix}P ( \{ θ \} \vert D , I ) = \frac{P ( \{ θ \} \vert I ) ( {\prod }_{k} \frac{1}{{σ}_{k} \sqrt{2 π}} ) exp ( - {\sum }_{k} \frac{1}{2 {σ}_{k}^{2}} {d}_{k}^{2} ) \frac{ \sqrt{π}}{\sqrt{{\sum }_{k} \frac{1}{2 {σ}_{k}^{2}} {m}_{k}^{2}}} exp ( \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} )}{\int d \{ θ \} P ( \{ θ \} \vert I ) ( {\prod }_{k} \frac{1}{{σ}_{k} \sqrt{2 π}} ) exp ( - {\sum }_{k} \frac{1}{2 {σ}_{k}^{2}} {d}_{k}^{2} ) \frac{ \sqrt{π}}{\sqrt{{\sum }_{k} \frac{1}{2 {σ}_{k}^{2}} {m}_{k}^{2}}} exp ( \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} )} \\ = \frac{P ( \{ θ \} \vert I ) ( {\prod }_{k} \frac{1}{{σ}_{k} \sqrt{2 π}} ) exp ( - {\sum }_{k} \frac{1}{2 {σ}_{k}^{2}} {d}_{k}^{2} ) \frac{ \sqrt{π}}{\sqrt{{\sum }_{k} \frac{1}{2 {σ}_{k}^{2}} {m}_{k}^{2}}} exp ( \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} )}{P ( D \vert I )} .\end{matrix}$$

Thus, the marginalization leaves a new equation for the likelihood of the parameters as follows:

$$P ( D \vert u , {ω}_{c} , I ) = ( {\prod }_{k} \frac{1}{{σ}_{k} \sqrt{2 π}} ) exp ( - {\sum }_{k} \frac{1}{2 {σ}_{k}^{2}} {d}_{k}^{2} ) \frac{ \sqrt{π}}{\sqrt{{\sum }_{k} \frac{1}{2 {σ}_{k}^{2}} {m}_{k}^{2}}} exp ( \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} )$$

where mₖ is short for the model mₖ(u, ω_{c}).

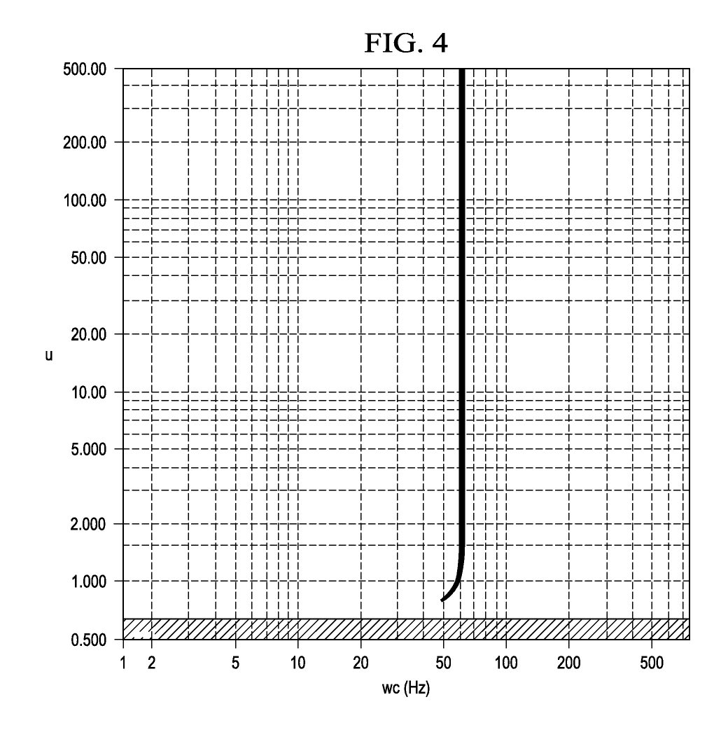

Since there are only two remaining parameters, this can be shown in a 2-dimensional graph. For the spectrum shown in FIG. 2, a gray-scale plot of (28) is shown in FIG. 4 with black indicating the highest likelihood at each u level. The thatched region at the bottom lies below the critical u value from (17) and is physically unrealizable. The isolated horizontal black line above the critical region indicates the maxiflat u value from (22). When the u value is above the maxiflat value, the peak likelihood region for ω_{c} is very stable, since the shape of the model frequency response changes only slightly as u increases. However when u goes below the maxiflat value the model frequency response quickly becomes peaky, and the most probable region for ω_{c} becomes less stable, changing value and jumping to a higher region before jumping to the lowest frequency as u nears its critical value.

Exact marginalization over u looks very difficult and numerically integrating over u also seems computationally expensive. However u doesn't affect the shape of the speaker rolloff very much beyond some low values which cause a large resonance in the model spectrum, as indicated by FIG. 3. Since loudspeaker designers try to avoid such resonances, it is unlikely such values for u will explain the data well. Instead we hold the value constant at a reasonable value such the maxiflat value u=1.5538, and evaluate the probability of ω_{c} on this basis.

In this example we have

$${P ( {ω}_{c} \vert D , I ) = \frac{( {\prod }_{k} \frac{1}{{σ}_{k} \sqrt{2 π}} ) exp ( - {\sum }_{k} \frac{1}{2 {σ}_{k}^{2}} {d}_{k}^{2} ) \frac{ \sqrt{π}}{\sqrt{{\sum }_{k} \frac{1}{2 {σ}_{k}^{2}} {m}_{k}^{2}}} exp ( \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} ) P ( {ω}_{c} \vert I )}{P ( D \vert I )} \vert}_{u = 1.5538} . \qquad ( 29 )$$

The prior P(ω_{c}|I) can be thought of as a weighting based on our belief about what likely values of ω_{c} should be. This can be flat over a reasonable range, or have some proprietary shape based on many loudspeaker evaluations. It is also useful to make the prior P(ω_{c}|I) discrete with the same set of frequencies bins used for the data. Thus the prior can state P(ω_{c}|I)=0 if c≠k for all frequency bin indexes k, effectively sampling the continuous probability density at some subset of frequency bins. Since the same prior is built into the normalizing denominator, this is a way to move from a continuous distribution to a discrete one defined only at bin frequencies.

A high level implementation of this method is shown in FIG. 5. The loudspeaker spectrum is assumed available from other processes, but if not, these can be calculated by taking the FFT of a test signal recording.

For implementation it is useful to take the log of (29) which gives

$$log ( P ( {ω}_{c} \vert D , I ) ) = log ( ( {\prod }_{k} \frac{1}{{σ}_{k} \sqrt{2 π}} ) ) {\sum }_{k} \frac{1}{2 {σ}_{k}^{2}} {d}_{k}^{2} \vert \frac{1}{2} log ( π ) - \frac{1}{2} log ( {\sum }_{k} \frac{1}{2 {σ}_{k}^{2}} {m}_{k}^{2} ) + \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} + log ( P ( {ω}_{c} \vert I ) ) - log ( P ( D \vert I ) ) . \qquad ( 30 )$$

which can be considered as

$$log ( P ( {ω}_{c} \vert D , I ) ) = - \frac{1}{2} log ( {\sum }_{k} \frac{1}{2 {σ}_{k}^{2}} {m}_{k}^{2} ) + \frac{{( {\sum }_{k} \frac{1}{{σ}_{k}^{2}} {d}_{k} {m}_{k} )}^{2}}{2 {\sum }_{k} \frac{1}{{σ}_{k}^{2}} {m}_{k}^{2}} + log ( P ( {ω}_{c} \vert I ) ) + constant . \qquad ( 31 )$$

Since log(x) is a monotonically increasing function of x and the constant term doesn't affect the location of the maximum value, one approach is just to find the ω_{c} which maximizes (31), ignoring the constant term. If a uniform probability is assumed for the prior probability P(ω_{c}|I), then this term can be left out as well.

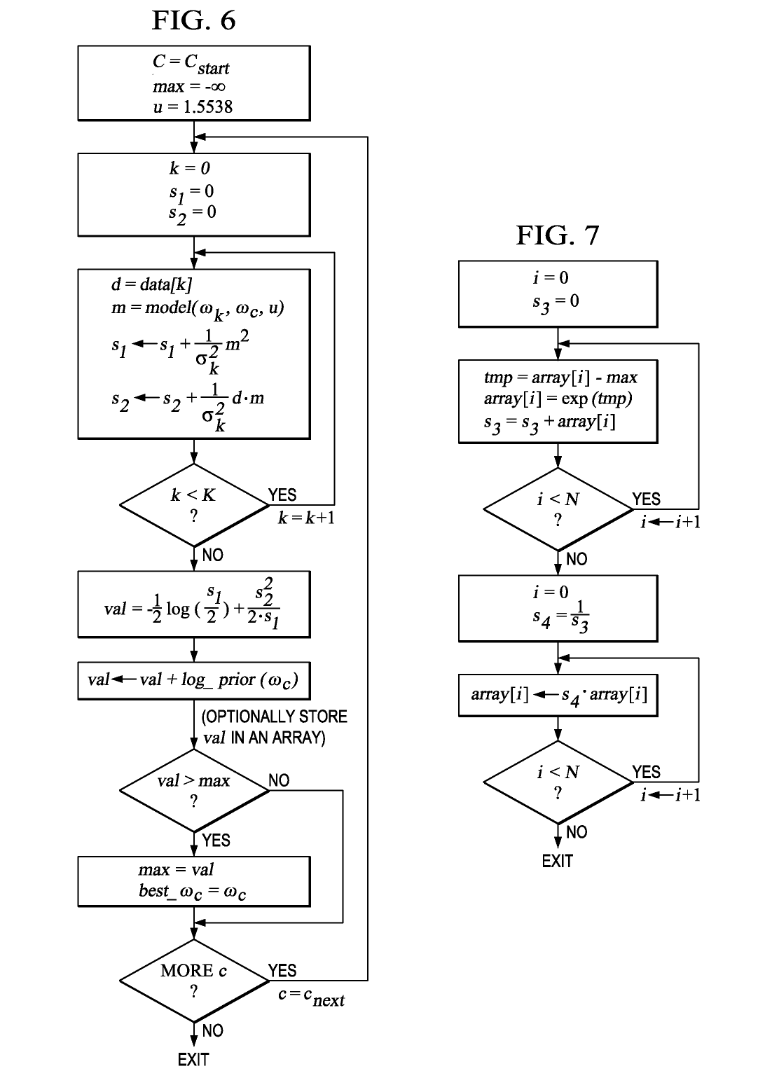

A block diagram of this implementation is given in FIG. 6. Here u is set to 1.5538 as an example. The data[k] is the squared magnitude of the spectrum, which can be calculated beforehand or directly when needed from the k^{th} value of the spectrum times its conjugate. The maximum value val determines the best cutoff best_ω_{c}. Optionally the values at each ω_{c} can be stored in an array for further processing.

If the results are stored for further processing, it is often desirable to convert the values to a probability distribution summing to 1. A way of doing this is shown in FIG. 7, which uses the max value found in FIG. 6.

Although any loudspeaker model function can be used in principle, an implementation of the loudspeaker model is given by (23).

While the foregoing is directed to embodiments of the present invention, other and further embodiments of the invention may be devised without departing from the basic scope thereof, and the scope thereof is determined by the claims that follow.

What is claimed is:

1. A method for enhancing cutoff detection of a loudspeaker, the method comprising:
retrieving a loudspeaker model cutoff and model error;
generating a probability distribution of the cutoff frequency based on the retrieved models; and
utilizing the generated probability distribution to enhance the detection of the cutoff of the loudspeaker.

2. The method of claim 1, wherein the model error is a Gaussian model error;

3. The method of claim 1, wherein the error relates to at least one of background noise, measurement error, room and speaker reflection or choosing the wrong model function.

3. An apparatus for enhancing cutoff detection of a loudspeaker, comprising:
means for retrieving a loudspeaker model cutoff and model error;
means for generating a probability distribution of the cutoff frequency based on the retrieved models;
means for utilizing the generated probability distribution to enhance the detection of the cutoff of the loudspeaker.

4. The apparatus of claim 1, wherein the model error is a Gaussian model error;

5. The apparatus of claim 1, wherein the error relates to at least one of background noise, measurement error, room and speaker reflection or choosing the wrong model function.

6. A computer readable medium comprising software that, when executed by a processor, causes the processor to perform a method for enhancing cutoff detection of a loudspeaker, the method comprising:
retrieving a loudspeaker model cutoff and model error;
generating a probability distribution of the cutoff frequency based on the retrieved models;
utilizing the generated probability distribution to enhance the detection of the cutoff of the loudspeaker.

7. The computer readable medium of claim 6, wherein the model error is a Gaussian model error;

8. The computer readable medium of claim 6, wherein the error relates to at least one of background noise, measurement error, room and speaker reflection or choosing the wrong model function.
